(19) United States
(12) Patent Application Publication
(10) Pub. No.: US 2022/0298858 A1
(43) Pub. Date: Sep. 22, 2022

(54) INTELLIGENT CONTROLLER FOR AUTOMATICALLY ADJUSTING SLAT ANGLES OF WINDOW SHUTTER

(71) Applicants: Xiaojian Li, Changsha City (CN); Ye Li, Huaihua City (CN)

(72) Inventors: Xiaojian Li, Changsha City (CN); Ye Li, Huaihua City (CN)

(21) Appl. No.: 17/336,316

(22) Filed: Jun. 2, 2021

(30) Foreign Application Priority Data
Mar. 18, 2021 (CN) 202110289384.3

(51) Int. Cl. E06B 9/70; E06B 9/06; E06B 9/88

(52) U.S. Cl. CPC E06B 9/70; E06B 9/0638; E06B 9/88; E06B 2009/6809

(57) ABSTRACT

The disclosure discloses an intelligent controller for automatically adjusting slat angles of a window shutter, comprising a controller box and a window shutter. The controller box comprises a body case, a battery, a control board, a motor and a linear bearing, the linear bearing is connected to the motor, a slide rod, which is retractable with respect to the linear bearing, is mounted on the linear bearing, and a rod slot is provided on a side face of the body case. The control board comprises a mainboard, a Hall board and a connection board which are connected in sequence, the Hall board, the connection board and the motor are electrically connected in sequence, and the mainboard is electrically connected to the battery. An interconnecting piece matched with the slide rod is provided on the window shutter, and the slide rod is retractable and slides along the rod slot to control the opening and closing of slats of the window shutter. According to the disclosure, the controller can be used with wireless remote control and mobile APPs to achieve control, which is intelligent and convenient and can greatly reduce the users' labor intensity. It adopts the lithium battery as a power supply and thus is safe and reliable. It is easy for installation and operation without any damage to the window shutter and wall structure and is suitable for self-installation by users.

### TECHNICAL FIELD

The disclosure relates to the technical field of intelligent control, in particular to an intelligent controller for automatically adjusting slat angles of a window shutter.

### BACKGROUND

Aluminum and wood window shutters are mainly used for sun shading, heat insulation, light transmission and ventilation, heat preservation and interior decoration, and all window shutters currently used by users are manual devices that require users to manually adjust slat angles to control the intensity of light into the room, so as to achieve indoor light intensity adjustment, sun shading and ventilation. Disadvantages are as follows. 1. As manual adjustment requires a certain intensity of labor, it is not easy for the elderly and the weak at home to use the window shutters; 2. In the intelligent home era, the manual window shutters cannot access intelligent platforms and therefore cannot realize intelligent linkage.

### SUMMARY

An objective of the disclosure is to provide an intelligent controller for automatically adjusting slat angles of a window shutter, to solve the problems described in the Background.

To solve the above technical problems, a technical solution provided by the disclosure is as follows.

An intelligent controller for automatically adjusting slat angles of a window shutter is provided, including a controller box and a window shutter, wherein

the controller box includes a body case, a battery, a control board, a motor and a linear bearing; the linear bearing is connected to the motor, a slide rod which is retractable with respect to the linear bearing is mounted on the linear bearing, and a rod slot is provided on a side face of the body case;

the control board includes a mainboard, a Hall board and a connection board which are connected in sequence, the Hall board, the connection board and the motor are electrically connected in sequence, and the mainboard is electrically connected to the battery; a microcontroller unit, a low dropout linear regulator, an RF module, a motor drive module, a Hall board connector and a battery detection module are provided on the mainboard, the low dropout linear regulator, the motor drive module and the battery detection module are all electrically connected to the battery, the RF module, the low dropout linear regulator, the battery detection module and the motor drive module are electrically connected to the microcontroller unit, and the Hall board connector is electrically connected to the motor drive module; and the Hall board connector is electrically connected to the Hall board; and

an interconnecting piece matched with the slide rod is provided on the window shutter, and the slide rod is retractable and slides along the rod slot to control the opening and closing of slats of the window shutter.

As a preferred embodiment, the battery is a lithium battery.

As a preferred embodiment, the battery is a dry battery.

As a preferred embodiment, an indicator light and a button are electrically connected to and provided on the microcontroller unit, and the button is a mechanical button.

As a preferred embodiment, the interconnecting piece is a control lever; the window shutter includes a top bracket, rope winders, slats, lifting ropes and a bottom bracket; the control lever is rotatably connected to the top bracket, and the rope winder is provided on the control rod; there are a plurality of the slats located below the top bracket; an upper end of the lifting rope is connected to the rope winder so as to connect the plurality of the slats in series, and the rope winder can lift the slats up and down and control the slats to turn over; and the bottom bracket around which the lifting rope can rotate is provided at a lower end of the blade at the bottom.

As a preferred embodiment, there are two steel wires vertically running through the plurality of the slats, the top bracket and the bottom bracket, and a fixture is provided at each end of the steel wire.

As a preferred embodiment, the plurality of the slats are vertically arranged in a linear array.

As a preferred embodiment, two mounting clips are symmetrically provided on the top bracket, and a stopper configured to prevent excessive rotation of the control lever is provided in the middle of the control lever.

As a preferred embodiment, the interconnecting piece is a rotating sleeve; the window shutter comprises a fixed support, turnover slats and a retainer sleeve; the controller box is fixed on the fixed support; there are a plurality of the turnover slats rotatably connected to the fixed support, the retainer sleeve is fixedly provided at one end of the turnover slat, and the rotating sleeve is provided on the retainer sleeve; and the slide rod passes through the rotating sleeve for driving the turnover slats to turn over.

As a preferred embodiment, there are a plurality of the turnover slats arranged in a linear array along the length direction of the fixed support.

The disclosure has the advantages as follows. The controller can be used with wireless remote control and mobile APPs to achieve control, which is intelligent and convenient and can greatly reduce the users' labor intensity. It adopts the lithium battery as a power supply and thus is safe and reliable. It is easy for installation and operation without any damage to the window shutter and wall structure and is suitable for self-installation by users.

### BRIEF DESCRIPTION OF DRAWINGS

FIG. 1 is a structural diagram of an intelligent controller for automatically adjusting slat angles of a window shutter according to an embodiment 1 of the disclosure;

FIG. 2 is a side view of the intelligent controller for automatically adjusting slat angles of a window shutter according to the embodiment 1 of the disclosure;

FIG. 3 is a sectional view of A-A in FIG. 2;

FIG. 4 is a partial enlarged view of A in FIG. 3;

FIG. 5 is a functional block diagram of a controller box in the intelligent controller for automatically adjusting slat angles of a window shutter;

FIG. 6 is a front view of an intelligent controller for automatically adjusting slat angles of a window shutter according to an embodiment 2 of the disclosure;

FIG. 7 is a structural diagram of the intelligent controller for automatically adjusting slat angles of a window shutter according to the embodiment 2 of the disclosure; and

FIG. 8 is a partial enlarged view of B in FIG. 7.

In figures: 1—Controller box; 2—Window shutter; 3—Shell; 4—Battery; 5—Control board; 6—Motor; 7—Linear bearing; 8—Slide rod; 9—Rod slot; 10—Main board; 11—Hall board; 12—Connection board; 13—Microcontroller unit; 14—Low dropout linear regulator; 15—RF module; 16—Motor drive module; 17—Battery detection module; 18—Hall board connector; 19—Control lever; 20—Indicator light; 21—Button; 22—Top bracket; 23—Rope winder; 24—Slat; 25—Lifting rope; 26—Bottom bracket; 27—Steel wire; 28—Fixture; 29—Mounting clip; 30—Stopper; 31—Rotating sleeve; 32—Fixed support; 33—Turnover slat; 34—Retainer sleeve.

### DETAILED DESCRIPTION OF THE PREFERRED EMBODIMENTS

In the description of the disclosure, it should be understood that the direction or position relations indicated by the terms “center”, “longitudinal”, “transverse”, “length”, “width”, “thickness”, “upper”, “lower”, “front”, “rear”, “left”, “right”, “vertical” and “horizontal” “top”, “bottom”, “inside”, “outside”, “clockwise” and “counterclockwise” are direction or position relations shown in the accompanying drawings, and these terms are used merely for ease of and for simplifying the description of the disclosure, not for indicating or implying that the devices or components referred to must have a special direction and be constructed and operated in a special direction. Therefore, these terms shall not be construed as limiting the disclosure.

Furthermore, the terms “first” and “second” are used merely for illustrative purposes and shall not be construed as indicating or implying relative importance or as implicitly specifying the number of technical features indicated. Thus, the features defined with the terms “first” and “second” may explicitly or implicitly include one or more of these features. Unless otherwise specifically defined, “a plurality of” means two or more in the description of the disclosure.

For ease of understanding of the disclosure, the disclosure will be more fully described below with reference to the accompanying drawings.

Preferred embodiments of the disclosure are shown in the accompanying drawings. However, the disclosure may be implemented in many different forms and is not limited to the embodiments described herein. Rather, these embodiments are provided for a more thorough and complete understanding of the disclosure of the disclosure.

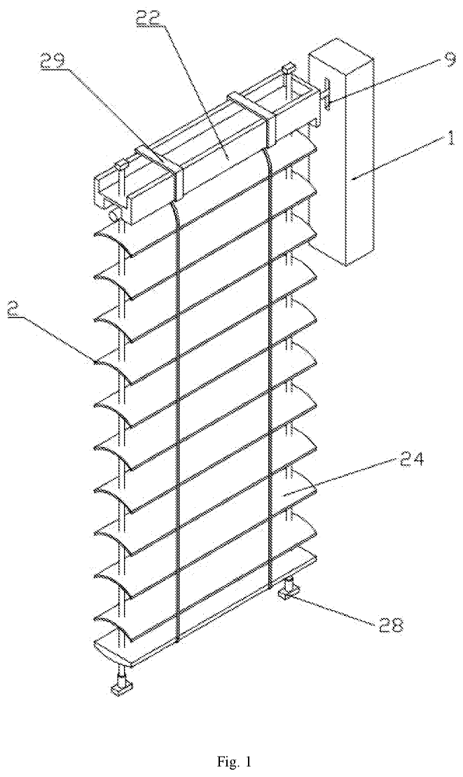

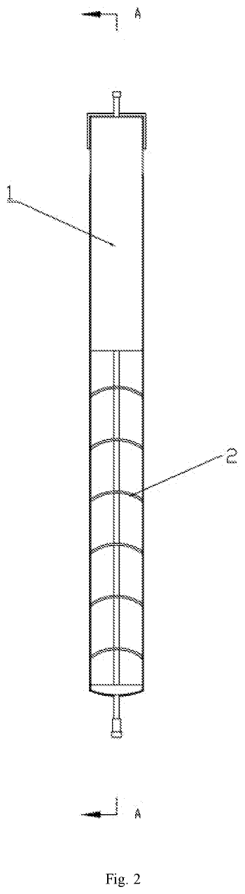

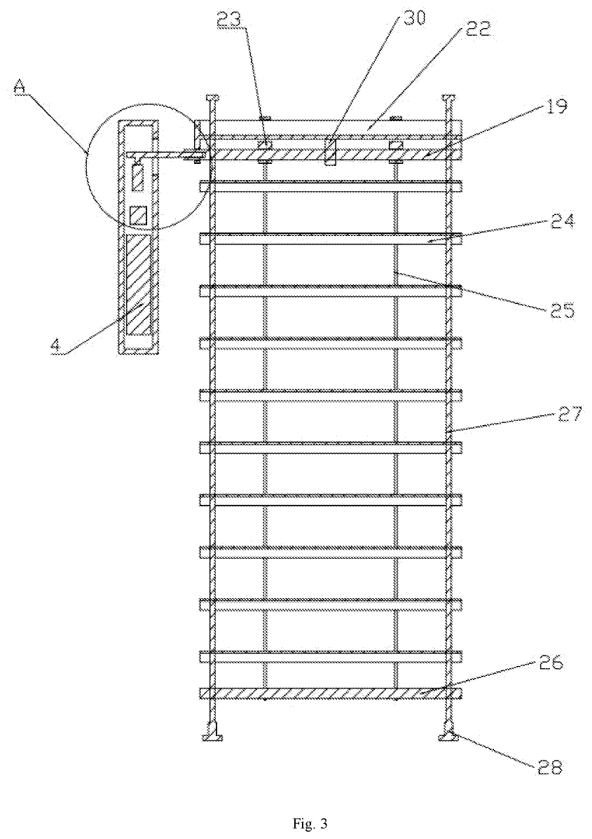

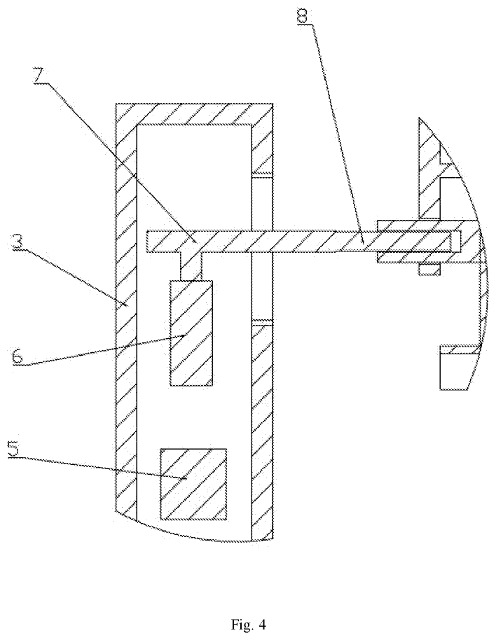

Embodiment 1: With reference to FIGS. 1 to 5, an intelligent controller for automatically adjusting slat angles of a window shutter is provided, including a controller box 1 and a window shutter 2.

The controller box 1 includes a body case 3, a battery 4, a control board 5, a motor 6 and a linear bearing 7; the linear bearing 7 is connected to the motor 6, a slide rod 8, which is retractable with respect to the linear bearing 7, is mounted on the linear bearing 7, and a rod slot 9 is provided on a side face of the body case 3.

The control board 5 includes a mainboard 10, a Hall board 11 and a connection board 12 which are connected in sequence, the Hall board 11, the connection board 12 and the motor 6 are electrically connected in sequence, and the mainboard 10 is electrically connected to the battery 4. A microcontroller unit 13, a low dropout linear regulator 14, an RF module 15, a motor drive module 16, a Hall board connector 18 and a battery detection module 17 are provided on the mainboard 10, the low dropout linear regulator 14, the motor drive module 16 and the battery detection module 17 are all electrically connected to the battery 4, the RF module 15, the low dropout linear regulator 14, the battery detection module 17 and the motor drive module 16 are electrically connected to the microcontroller unit 13, and the Hall board connector 18 is electrically connected to the motor drive module 16. The Hall board connector 18 is electrically connected to the Hall board 11.

An interconnecting piece matched with the slide rod 8 is provided on the window shutter 2, and the slide rod 8 is retractable and slides along the rod slot 9 to control the opening and closing of slats of the window shutter 2.

In this embodiment, the battery 4 is a lithium battery.

In this embodiment, the battery 4 is a dry battery.

In this embodiment, an indicator light 20 and a button 21 are electrically connected to and provided on the microcontroller unit 13, and the button 21 is a mechanical button.

In this embodiment, the interconnecting piece is a control lever 19. The window shutter 2 includes a top bracket 22, rope winders 23, slats 24, lifting ropes 25 and a bottom bracket 26. The control lever 19 is rotatably connected to the top bracket 22, and the rope winder 23 is provided on the control rod 19. There are a plurality of the slats 24 located below the top bracket 22. An upper end of the lifting rope 25 is connected to the rope winder 23 so as to connect the plurality of the slats 24 in series, and the rope winder 23 can lift the slats 24 up and down and control the slats 24 to turn over. The bottom bracket 26 around which the lifting rope 25 can rotate is provided at a lower end of the blade 24 at the bottom.

In this embodiment, there are two steel wires 27 vertically running through the plurality of the slats 24, the top bracket 22 and the bottom bracket 26, and a fixture 28 is provided at each end of the steel wire 27.

In this embodiment, the plurality of the slats 24 are vertically arranged in a linear array.

In this embodiment, two mounting clips 29 are symmetrically provided on the top bracket 22, and a stopper 30 configured to prevent excessive rotation of the control lever 19 is provided in the middle of the control lever 19.

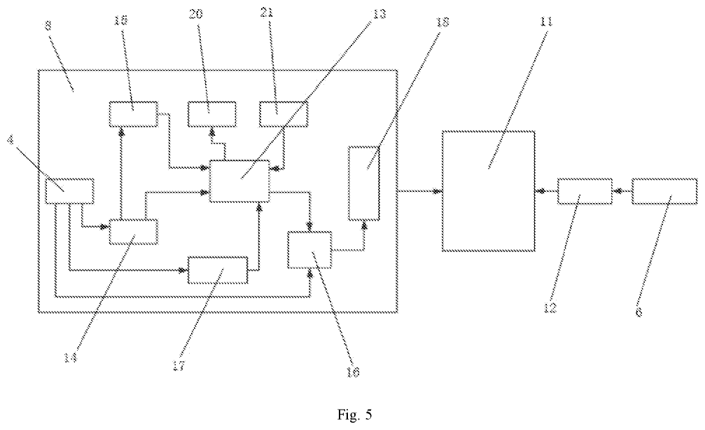

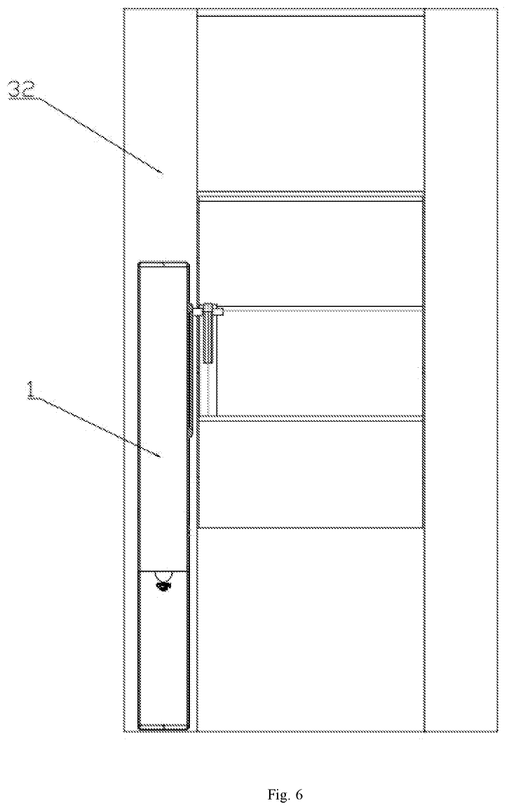

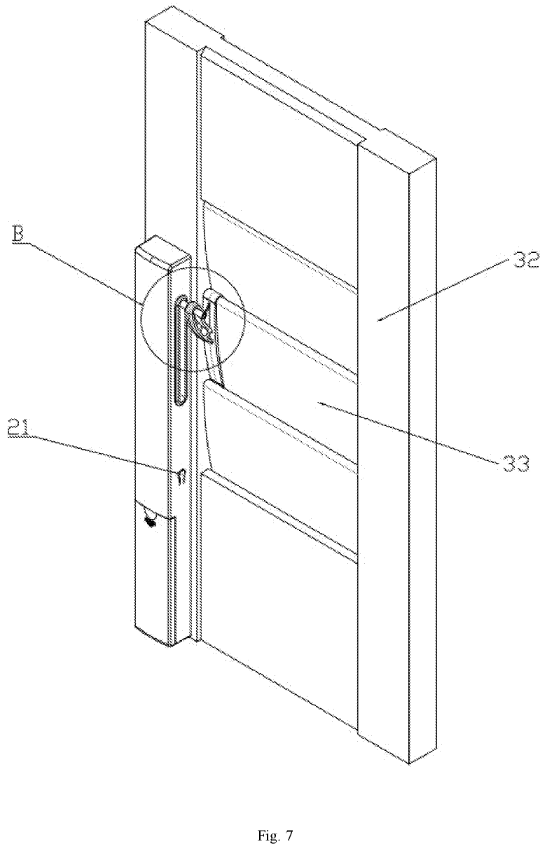

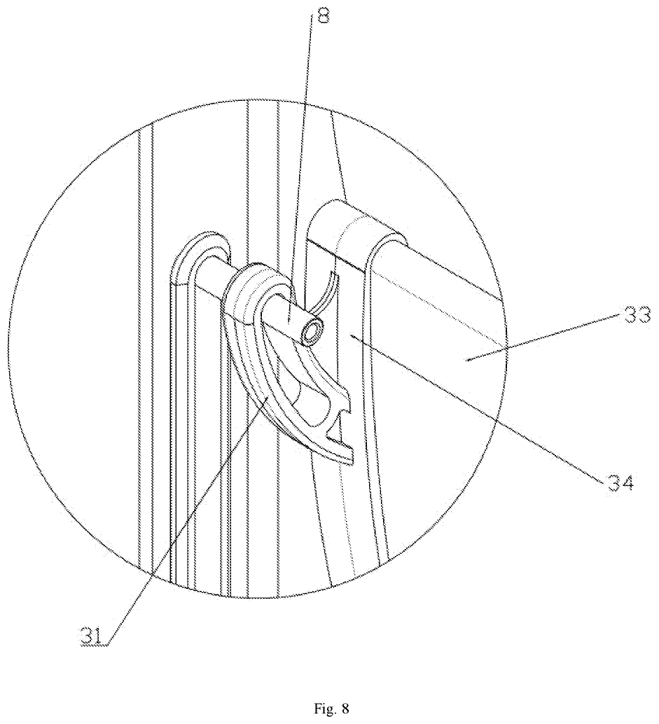

Embodiment 2: With reference to FIGS. 5 to 8, an intelligent controller for automatically adjusting slat angles of a window shutter is provided, including a controller box 1 and a window shutter 2.

The controller box 1 includes a body case 3, a battery 4, a control board 5, a motor 6 and a linear bearing 7; the linear bearing 7 is connected to the motor 6, a slide rod 8, which is retractable with respect to the linear bearing 7, is mounted on the linear bearing 7, and a rod slot 9 is provided on a side face of the body case 3.

The control board 5 includes a mainboard 10, a Hall board 11 and a connection board 12 which are connected in sequence, the Hall board 11, the connection board 12 and the motor 6 are electrically connected in sequence, and the mainboard 10 is electrically connected to the battery 4. A microcontroller unit 13, a low dropout linear regulator 14, an RF module 15, a motor drive module 16, a Hall board connector 18 and a battery detection module 17 are provided on the mainboard 10, the low dropout linear regulator 14, the motor drive module 16 and the battery detection module 17 are all electrically connected to the battery 4, the RF module 15, the low dropout linear regulator 14, the battery detection module 17 and the motor drive module 16 are electrically connected to the microcontroller unit 13, and the Hall board connector 18 is electrically connected to the motor drive module 16. The Hall board connector 18 is electrically connected to the Hall board 11.

An interconnecting piece matched with the slide rod 8 is provided on the window shutter 2, and the slide rod 8 is retractable and slides along the rod slot 9 to control the opening and closing of slats of the window shutter 2.

In this embodiment, the battery 4 is a lithium battery.

In this embodiment, the battery 4 is a dry battery.

In this embodiment, an indicator light 20 and a button 21 are electrically connected to and provided on the microcontroller unit 13, and the button 21 is a mechanical button.

In this embodiment, the interconnecting piece is a rotating sleeve 31. The window shutter 2 includes a fixed support 32, turnover slats 33 and a retainer sleeve 34. The controller box 1 is fixed on the fixed support 32. There

are a plurality of the turnover slats 33 rotatably connected to the fixed support 32, the retainer sleeve 34 is fixedly provided at one end of the turnover slat 33, and the rotating sleeve 31 is provided on the retainer sleeve 34. The slide rod 8 passes through the rotating sleeve 31 for driving the turnover slats 33 to turn over.

In this embodiment, there are a plurality of the turnover slats 33 arranged in a linear array along the length direction of the fixed support 32.

The parameters of each module in FIG. 5 are as follows.

| Item | Parameter | | Remarks |
|---|---|---|---|
| Power supply | 6 VDC 1 A | | 4 dry batteries |
| RF | 433.92 | MHz | |
| Output power | ≤6 | W | |

| | | |
|---|---|---|
| Standby current | TBD | |
| Remote control | TBD | Open space |
| Service temperature | −30° C.-85° C. | |
| Storage temperature | −40° C.-85° C. | |

1. Battery: 4 dry batteries configured to supply power to the motor and system.

2. RF module: ASK low-power receiver module with a frequency of 433.92 MHz. An antenna is a spring antenna or on-board or conductor antenna configured to receive signals. The RF module converts the signals to the microcontroller unit, and then the microcontroller unit enables operations based on the signals.

3. Low dropout linear regulator: 3.3V, and it is configured to supply power to the RF module and the microcontroller unit.

4. Microcontroller unit: 8-bit MCU, 8Kflash.

5. Motor driver IC: SOP8, 1 A output.

6. Button: horizontal touch button *1; set the stroke.

7. Indicator light: red and blue, 0805, indicating the current status.

8. Hall board: independent small board, cable connection, SOT-23 Hall switch *2, configured to detect the current motion state of the motor.

9. Hall board connector: 1*6P SMT connector with a spacing of 1.25 mm.

10. Power detection module: it is configured to output a signal to the microcontroller unit to turn on the light when the battery power is low.

Performance parameters are shown in the table below.

In the specific implementation of the disclosure, the installation method includes the following steps of fixing the controller of the disclosure on one side of a frame of the window shutter with 3M tape, inserting the slide rod into the control lever or the rotating sleeve of the window shutter, and setting up stop positions, thus realizing intelligent control. It can be powered by four 1.5V dry batteries or lithium batteries together with solar panels.

The operating principle of the disclosure is as follows. The motor is controlled by the control board to drive the linear bearing. In Embodiment 1, the slide rod on the linear bearing makes linear reciprocating motion in the axial direction, so as to drive the slats of the window shutter to turn 180 degrees up and down. In Embodiment 2, the slide rod on the linear bearing makes linear reciprocating motion in the direction of the rod slot, so as to drive the slats of the window shutter to turn 180 degrees up and down.

The technical features of the above embodiments may be combined in any way. For the sake of brevity, not all possible combinations of the technical features of the above embodiments have been described. However, all combinations of these technical features shall be considered as falling within the scope of the Specification in case of no contradiction therein. The embodiments described above are merely illustrative of several embodiments of the disclosure, which are described more specifically and in detail and shall not be construed as limiting the scope of the disclosure. It should be noted that a number of modifications and improvements may be made by those of ordinary skill in the art without departing from the concept of the disclosure, all of which shall fall within the scope of the disclosure. Accordingly, the protection scope of the disclosure should be subject to the protection scope defined by the claims.

1. An intelligent controller for automatically adjusting slat angles of a window shutter, comprising a controller box (1) and a window shutter (2), wherein
the controller box (1) comprises a body case (3), a battery (4), a control board (5), a motor (6) and a linear bearing (7); the linear bearing (7) is connected to the motor (6), a slide rod (8), which is retractable with respect to the linear bearing (7), is mounted on the linear bearing (7), and a rod slot (9) is provided on a side face of the body case (3);
the control board (5) comprises a mainboard (10), a Hall board (11) and a connection board (12) which are connected in sequence, the Hall board (11), the connection board (12) and the motor (6) are electrically connected in sequence, and the mainboard (10) is electrically connected to the battery (4); a microcontroller unit (13), a low dropout linear regulator (14), an RF module (15), a motor drive module (16), a Hall board connector (18) and a battery detection module (17) are provided on the mainboard (10), the low dropout linear regulator (14), the motor drive module (16) and the battery detection module (17) are all electrically connected to the battery (4), the RF module (15), the low dropout linear regulator (14), the battery detection module (17) and the motor drive module (16) are electrically connected to the microcontroller unit (13), and the Hall board connector (18) is electrically connected to the motor drive module (16); and the Hall board connector (18) is electrically connected to the Hall board (11); and
an interconnecting piece matched with the slide rod (8) is provided on the window shutter (2), and the slide rod (8) is retractable and slides along the rod slot (9) to control the opening and closing of slats of the window shutter (2).

2. The intelligent controller for automatically adjusting slat angles of a window shutter according to claim 1, wherein the battery (4) is a lithium battery.

3. The intelligent controller for automatically adjusting slat angles of a window shutter according to claim 1, wherein the battery (4) is a dry battery.

4. The intelligent controller for automatically adjusting slat angles of a window shutter according to claim 3, wherein an indicator light (20) and a button (21) are electrically connected to and provided on the microcontroller unit (13), and the button (21) is a mechanical button.

5. The intelligent controller for automatically adjusting slat angles of a window shutter according to claim 1, wherein the interconnecting piece is a control lever (19); the window shutter (2) comprises a top bracket (22), rope winders (23), slats (24), lifting ropes (25) and a bottom bracket (26); the control lever (19) is rotatably connected to the top bracket (22), and the rope winder (23) is provided on the control rod (19); there are a plurality of the slats (24) located below the top bracket (22); an upper end of the lifting rope (25) is connected to the rope winder (23) so as to connect the plurality of the slats (24) in series, and the rope winder (23) can lift the slats (24) up and down and control the slats (24) to turn over; and the bottom bracket (26) around which the lifting rope (25) can rotate is provided at a lower end of the blade (24) at the bottom.

6. The intelligent controller for automatically adjusting slat angles of a window shutter according to claim 5, wherein there are two steel wires (27) vertically running through the plurality of the slats (24), the top bracket (22) and the bottom bracket (26), and a fixture (28) is provided at each end of the steel wire (27).

7. The intelligent controller for automatically adjusting slat angles of a window shutter according to claim 5, wherein the plurality of the slats (24) are vertically arranged in a linear array.

8. The intelligent controller for automatically adjusting slat angles of a window shutter according to claim 5, wherein two mounting clips (29) are symmetrically provided on the top bracket (22), and a stopper (30) configured to prevent excessive rotation of the control lever (19) is provided in the middle of the control lever (19).

9. The intelligent controller for automatically adjusting slat angles of a window shutter according to claim 1, wherein the interconnecting piece is a rotating sleeve (31); the window shutter (2) comprises a fixed support (32), turnover slats (33) and a retainer sleeve (34); the controller box (1) is fixed on the fixed support (32); there are a plurality of the turnover slats (33) rotatably connected to the fixed support (32), the retainer sleeve (34) is fixedly provided at one end of the turnover slat (33), and the rotating sleeve (31) is provided on the retainer sleeve (34); and the slide rod (8) passes through the rotating sleeve (31) for driving the turnover slats (33) to turn over.

10. The intelligent controller for automatically adjusting slat angles of a window shutter according to claim 9, wherein there are a plurality of the turnover slats (33) arranged in a linear array along the length direction of the fixed support (32).
